(19) United States
(12) Patent Application Publication
(10) Pub. No.: US 2026/0186086 A1
(43) Pub. Date: Jul. 2, 2026

(54) METHOD AND SYSTEM FOR DETECTING OBJECT WITHIN PREDETERMINED REGION AROUND MAGNETIC RESONANCE IMAGING DEVICE

(71) Applicant: GE Precision Healthcare LLC, Waukesha, WI (US)

(72) Inventors: Qingyu Dai, Beijing (CN); Jie Wang, Beijing (CN); Xiaolan Liu, Beijing (CN); Fan Yang, Beijing (CN); Kun Wang, Beijing (CN)

(21) Appl. No.: 19/425,715

(22) Filed: Dec. 18, 2025

(30) Foreign Application Priority Data
Dec. 26, 2024 (CN) 202411943337.6

(51) Int. Cl. G01R 33/28; G01R 33/56

(52) U.S. Cl. CPC G01R 33/288; G01R 33/5608

(57) ABSTRACT

A method and system are provided for detecting an object within a predetermined region around a magnetic resonance imaging device. The method comprises: acquiring an image captured for a space where the magnetic resonance imaging device is located, the image including an edge of at least a portion of the predetermined region around the magnetic resonance imaging device; performing object detection according to the image; and determining, according to a result of the object detection and position information of at least the portion of the predetermined region, whether the object exists within the predetermined region. This approach enables detection of an object within a restricted region of a magnetic resonance imaging device, thereby achieving safety monitoring of the environment around the magnetic resonance imaging device.

### CROSS REFERENCE TO RELATED APPLICATIONS

The present application claims priority and benefit of Chinese Patent Application No. 202411943337.6 filed on Dec. 26, 2024, which is incorporated herein by reference in its entirety.

### TECHNICAL FIELD

Embodiments of the present application relate to the technical field of medical equipment, and in particular, to a method and a system for detecting an object within a predetermined region around a magnetic resonance imaging device.

### BACKGROUND

A magnetic resonance imaging device includes a magnet system, a gradient magnetic field system, a radio frequency system, a computer, and an image processing system, in which a magnet generates a strong fringe field of magnet. Any metal objects that enter the fringe field of magnet may be attracted and rapidly move toward and adhere to the magnet, resulting in safety hazards.

Operators of magnetic resonance imaging devices require specialized training on how to operate safely outside the range of the fringe field of magnet. For example, during maintenance, repair, or replacement of parts of the magnetic resonance imaging devices, the operators need to pay great attention and strictly abide by relevant safety regulations, and avoid bringing metal objects into the magnetic field area.

It should be noted that the above introduction of the background is only for the convenience of clearly and completely describing the technical solutions of the present application, and for the convenience of understanding for those skilled in the art.

### SUMMARY

The inventors of the present application have discovered that it is typical in the prior art to post a warning line around a magnetic resonance imaging device to remind operators not to bring metal components into the fringe field of magnet. However, this approach has a certain impact on the environment cleanliness of the magnetic resonance room and may interfere with the normal operation of the magnetic resonance imaging device. More importantly, whether a metal object enters the fringe field of magnet depends entirely on the subjective judgment of the on-site operator. If the operator forgets that they are carrying a metal object or fails to notice the warning line and thus brings the metal object into the region of the fringe field of magnet, this approach cannot detect the risk and may cause damage.

In order to solve the above technical problem or at least similar technical problems, embodiments of the present application provide a method and a system for detecting an object within a predetermined region around a magnetic resonance imaging device. The method is used to acquire an image including an edge of at least a portion of the predetermined region around the magnetic resonance imaging device, perform object detection according to the image, and determine, according to a result of the object detection and position information of at least the portion of the predetermined region, whether the object exists within the predetermined region. In this way, an object within a restricted region of the magnetic resonance imaging device is detected, achieving safety monitoring of the environment around the magnetic resonance imaging device.

According to one aspect of the embodiments of the present application, a method for detecting an object within a predetermined region around a magnetic resonance imaging device is provided, the method includes acquiring an image captured for a space where the magnetic resonance imaging device is located. The image comprises an edge of at least a portion of the predetermined region around the magnetic resonance imaging device. The method further includes performing object detection according to the image; and determining, according to a result of the object detection and position information of at least the portion of the predetermined region, whether the object exists within the predetermined region.

According to one aspect of the embodiments of the present application, a system for detecting an object within a predetermined region around a magnetic resonance imaging device is provided. The system includes a memory and a processor. The memory stores a computer program. The processor is configured to execute the computer program to implement any of the foregoing features of the method for detecting an object within a predetermined region around a magnetic resonance imaging device.

One of the beneficial effects of the embodiments of the present application is that: the method automatically determines whether an object exists within the predetermined region around the magnetic resonance imaging device by detecting the position of the object in the acquired image, thereby achieving safety monitoring of the environment around the magnetic resonance imaging device.

With reference to the following description and drawings, specific implementations of the embodiments of the present application are disclosed in detail, and the way in which the principles of the embodiments of the present application can be employed is illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of an application scenario of detecting an object within a predetermined region around a magnetic resonance imaging device according to an embodiment of the present application;

FIG. 3 is a schematic cross-sectional view of a fringe field of magnet generated by a magnet of a magnetic resonance imaging device;

FIG. 4 is another schematic cross-sectional view of a fringe field of magnet generated by a magnet of a magnetic resonance imaging device;

FIG. 5 is yet another schematic cross-sectional view of a fringe field of magnet generated by a magnet of a magnetic resonance imaging device;

FIG. 6 is a schematic diagram of a method for detecting an object within a predetermined region around a magnetic resonance imaging device according to an embodiment of the present application;

FIG. 7 is a schematic diagram of a method for detecting an object within a predetermined region around a magnetic resonance imaging device according to Embodiment 1 of the present application;

FIG. 8 is a schematic diagram of a method for detecting an object within a predetermined region around a magnetic resonance imaging device according to Embodiment 2 of the present application;

FIG. 9 is a schematic diagram of a method for detecting an object within a predetermined region around a magnetic resonance imaging device according to Embodiment 3 of the present application;

FIG. 10 is a schematic diagram of a method for detecting an object within a predetermined region around a magnetic resonance imaging device according to Embodiment 4 of the present application;

FIG. 11 is a schematic diagram of a three-dimensional fringe field of magnet of a magnet of a magnetic resonance imaging device according to an embodiment of the present application;

FIG. 12 is a schematic diagram of a method for predicting a motion trajectory of an object according to an embodiment of the present application;

FIG. 13 is a schematic diagram of a camera calibration tool according to an embodiment of the present application;

FIG. 14 is a schematic diagram of an apparatus for detecting an object within a predetermined region around a magnetic resonance imaging device according to an embodiment of the present application;

FIG. 15 is a schematic diagram of a system for detecting an object within a predetermined region around a magnetic resonance imaging device according to an embodiment of the present application;

FIG. 16 is a schematic diagram of detecting human body information and extracting a first region from a two-dimensional image captured in a single field of view for a space where a magnetic resonance imaging device is located;

FIG. 17 is a schematic diagram of an enlarged view of the first region extracted in FIG. 16;

FIG. 18 is a schematic diagram in which results of the human body information detection and the first region extraction in FIG. 16 are mapped to a depth image in the same field of view; and

FIG. 19 is a schematic diagram showing a result of segmentation performed in conjunction with information of a two-dimensional image and a depth image.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc., are used to distinguish different elements, but do not represent a spatial arrangement or temporal order, etc., of these elements, and these elements should not be limited by these terms. The term “and/or” includes any and all combinations of one or more associated listed terms. The terms “comprise”, “include”, “have”, etc., refer to the presence of described features, elements, components, or assemblies, but do not exclude the presence or addition of one or more other features, elements, components, or assemblies.

In the embodiments of the present application, the singular forms “a” and “the” include the plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ” and the term “on the basis of” should be construed as “at least in part on the basis of . . . ”, unless otherwise specified in the context.

In the embodiments of the present application, the term “key point” may be equivalently replaced with “key coordinate point”, “landmark”, “landmark point”, or the like. The term “subject” may be equivalently replaced with “examination subject”, “examined subject”, “scanned subject”, “subject to be scanned”, “patient”, etc., which may be a person, an animal, or other objects, etc. The term “object” may be equivalently replaced with “detection object”, “detected object”, or “research subject”, etc., which may be a part or other components, etc.

In the embodiments of the present application, the term “include/comprise” when used herein refers to the presence of features, integrated components, steps, or assemblies, but does not preclude the presence or addition of one or more other features, integrated components, steps, or assemblies.

The features described and/or illustrated for one implementation may be used in one or more other implementations in the same or similar way, be combined with features in other implementations, or replace features in other implementations.

In the embodiments of the present application, the apparatus for detecting an object within a predetermined region around a magnetic resonance imaging device may be applicable to various medical imaging scenarios, including, but not limited to, magnetic resonance imaging (MRI), computed tomography (CT), ultrasound imaging, positron emission tomography (PET), single photon emission computed tomography (SPECT), PET/CT, PET/MR, or any other suitable medical imaging scenarios.

In the embodiments of the present application, the method, apparatus and system of the present application are exemplarily described by taking an MRI scenario as an example. It should be understood that the contents of the embodiments of the present application are also applicable to other medical imaging scenarios.

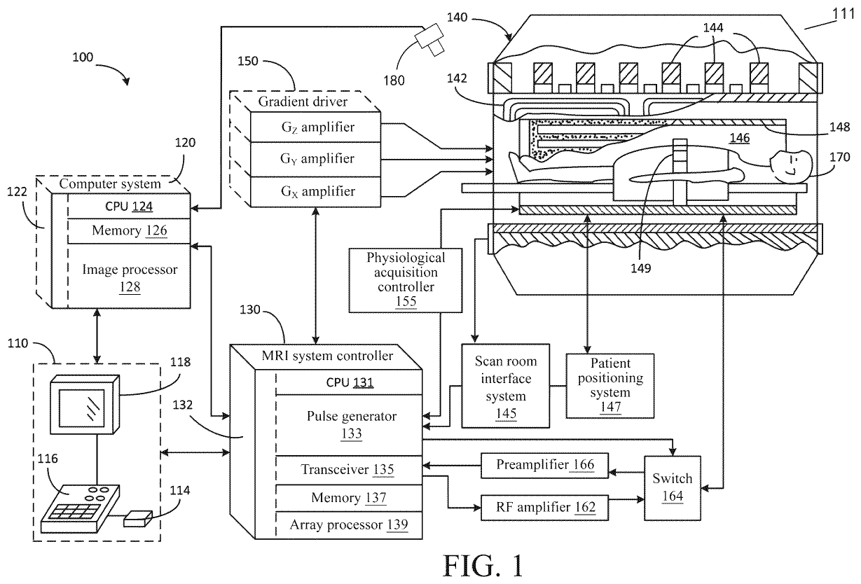

For ease of understanding, FIG. 1 is a schematic diagram of a magnetic resonance imaging (MRI) system 100 according to an embodiment of the present application.

The MRI system 100 includes a scanning unit 111. The scanning unit 111 is used to perform a magnetic resonance scan of a subject (e.g., a human body) 170 to generate image data of a region of interest of the subject 170, wherein the region of interest may be a pre-determined anatomical site or anatomical tissue.

The operation of the MRI system 100 is controlled by an operator workstation 110 that includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and in communication with a computer system 120 that enables an operator to control the generation and display of images on the display 118. The computer system 120 includes various components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by medical imaging functions implemented in the CPU 124. The computer system 120 may be connected to an archive media device, a persistent or backup memory, or a network. The computer system 120 may be coupled to and communicates with a separate MRI system controller 130.

The MRI system controller 130 includes a set of components that communicate with one another via an electrical and/or data connection module 132. The connection module 132 may employ a direct wired connection, a fiber optic connection, a wireless communication link, etc. The MRI system controller 130 may include a CPU 131, a sequence pulse generator (also known as a pulse generator) 133 in communication with the operator workstation 110, a transceiver (also known as an RF transceiver) 135, a memory 137, and an array processor 139.

In some embodiments, the sequence pulse generator 133 may be integrated into a resonance assembly 140 of the scanning unit 111 of the MRI system 100. The MRI system controller 130 may receive a command from the operator workstation 110, and is coupled to the scanning unit 111 to indicate an MRI scanning sequence to be performed during an MRI scan, so as to be used to control the scanning unit 111 to perform the flow of the aforementioned magnetic resonance scan. The MRI system controller 130 is further coupled to a gradient driver system (also known as gradient driver) 150 and is in communication therewith, and the gradient driver system is coupled to a gradient coil assembly 142 to generate a magnetic field gradient during an MRI scan.

The sequence pulse generator 133 may further receive data from a physiological acquisition controller 155 that receives signals from a plurality of different sensors (e.g., electrocardiogram (ECG) signals from electrodes attached to a patient, etc.), the sensors being connected to a subject or patient 170 undergoing an MRI scan. The sequence pulse generator 133 is coupled to and in communication with a scan room interface system 145 that receives signals from various sensors associated with the state of the resonance assembly 140. The scan room interface system 145 is further coupled to and in communication with a patient positioning system 147 that sends and receives signals to control movement of a patient table to a desired position to perform the MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} gradient amplifiers excites a corresponding gradient coil in the gradient coil assembly 142, so as to generate a magnetic field gradient used to spatially encode an MR signal during an MRI scan. The gradient coil assembly 142 is disposed within the resonance assembly 140, and the resonance assembly further includes a superconducting magnet having a superconducting coil 144 that, in operation, provides a static uniform longitudinal magnetic field B₀ throughout a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146. The resonance assembly 140 may further include an RF surface coil 149 for imaging different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kₓ direction in the k-space, the y direction may be referred to as a phase encoding direction or a k_{y} direction in the k-space, and the z direction may be referred to as a layer surface selection (layer selection) direction. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses amplified by an RF amplifier 162, and provides the same to the RF body coil 148 through a transmit/receive switch (also known as T/R switch or switch) 164.

As described above, the RF body coil 148 and the RF surface coil 149 may be used to transmit RF excitation pulses and/or receive resulting MR signals from the patient undergoing the MRI scan. The MR signals emitted by excited nuclei in the patient of the MRI scan may be sensed and received by the RF body coil 148 or the RF surface coil 149 and sent back to a preamplifier 166 through the T/R switch 164. The T/R switch 164 may be controlled by a signal from the sequence pulse generator 133 to electrically connect the RF amplifier 162 to the RF body coil 148 in the transmit mode and to connect the preamplifier 166 to the RF body coil 148 in the receive mode. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored in the memory 137 for post-processing as a raw k-space data array. A reconstructed magnetic resonance image may be obtained by transforming/processing the stored raw k-space data.

In some embodiments, the MR signals sensed and received by the RF body coil 148 or the RF surface coil 149 and amplified by the preamplifier 166 are demodulated, filtered, and digitized in a receiving portion of the transceiver 135, and transmitted to the memory 137 in the MRI system controller 130. For each image to be reconstructed, the data is rearranged into separate k-space data arrays, each of these separate k-space data arrays is input into the array processor 139, and the array processor is operated to transform the data into an array of image data by Fourier transform.

The array processor 139 uses transform methods, most commonly Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 1 is intended for illustration. Suitable MRI systems may include more, fewer, and/or different components.

The MRI system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, medical imaging, etc. For example, the storage medium may store a computer program for determining an orientation of an object according to the embodiments of the present invention. The described storage medium may include, for example, a ROM, a floppy disk, a hard disk, an optical disk, a magneto-optical disk, a CD-ROM, or a non-volatile memory card.

The camera 180 may capture an image of the subject 170.

### Embodiments of First Aspect

The embodiments of the first aspect of the present application provide a method for detecting an object within a predetermined region around a magnetic resonance imaging device. A scenario where the method is applied may be a magnetic resonance (MR) examination room where a magnetic resonance imaging device is placed.

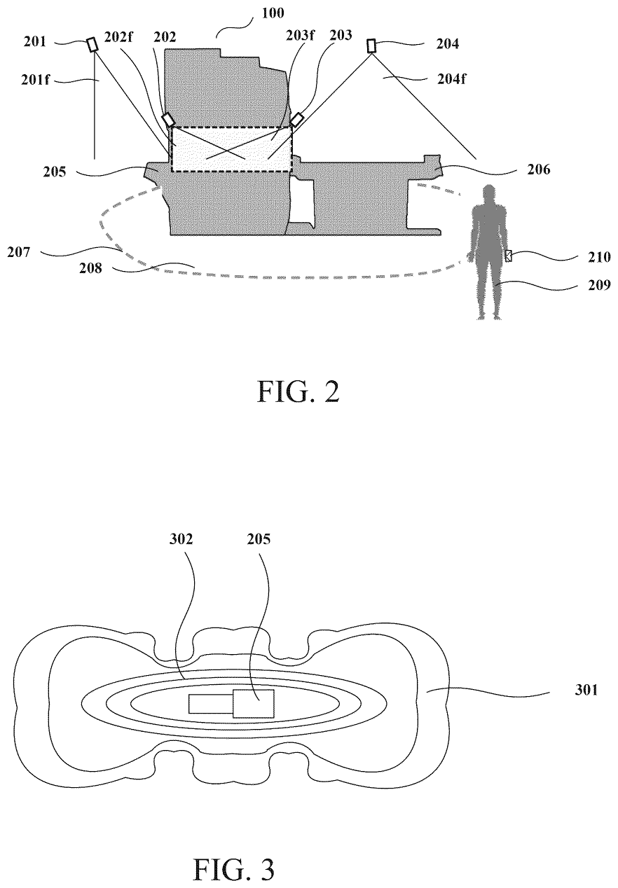

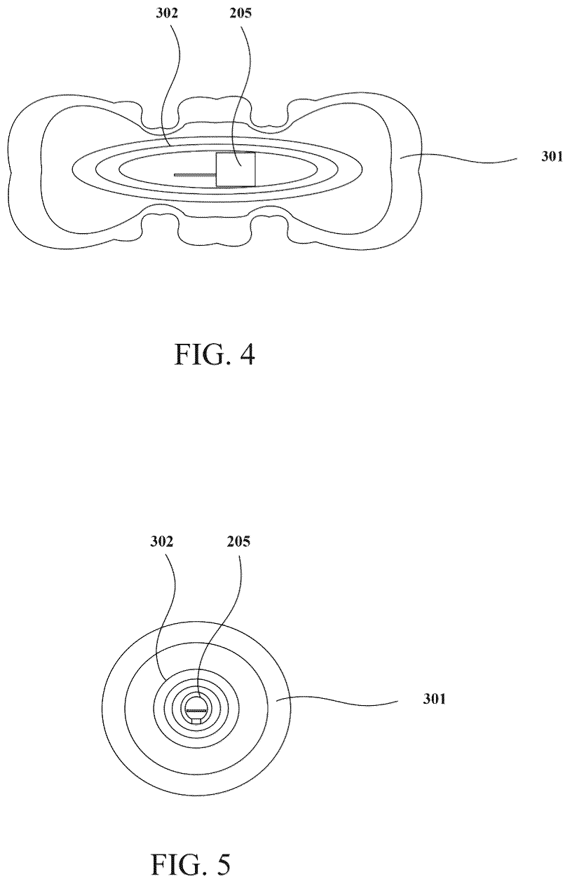

FIG. 2 is a schematic diagram of an application scenario of detecting an object within a predetermined region around a magnetic resonance imaging device according to an embodiment of the present application. FIG. 3 is a cross-sectional schematic diagram of a fringe field of magnet generated by a magnet of the magnetic resonance imaging device. FIG. 4 is another cross-sectional schematic diagram of the fringe field of magnet generated by the magnet of the magnetic resonance imaging device. FIG. 5 is yet another cross-sectional schematic diagram of the fringe field of magnet generated by the magnet of the magnetic resonance imaging device.

FIG. 3 is a schematic diagram of the distribution of a fringe field of magnet on a plane parallel to the ground (for example, a schematic diagram of a fringe field of magnet 301 when the magnetic resonance imaging device 100 is viewed from the top). FIG. 4 is a schematic diagram of the distribution of the fringe field of magnet 301 on a cross-section perpendicular to the ground and parallel to a length direction of an examination table 206 (i.e., a direction in which the examination table 206 advances and retreats relative to a magnet 205) (for example, a schematic diagram of the fringe field of magnet 301 when the magnetic resonance imaging device 100 is viewed from a side). FIG. 5 is a schematic diagram of the distribution of the fringe field of magnet 301 on a cross-section perpendicular to the ground and perpendicular to the length direction of the examination table 206 (i.e., a direction in which the examination table 206 advances and retreats relative to the magnet 205) (for example, a schematic diagram of the fringe field of magnet 301 when the magnetic resonance imaging device 100 is viewed in the length direction of the examination table 206).

As shown in FIG. 2, the application scenario includes the magnetic resonance imaging device 100. The application scenario further includes at least one of cameras 201, 202, 203, and 204. The magnetic resonance imaging device 100 includes the magnet 205 and the examination table 206, the magnet 205 generates the fringe field of magnet 301 (as shown in FIG. 3, FIG. 4 and FIG. 5), and a region where an object 210 is restricted from entering is called a predetermined region (or, a predetermined magnetic field region) 208. The predetermined region 208 has an edge 207, and the edge 207 corresponds to, for example, a position defined by a 200 Gauss (G) line 302 in the fringe field of magnet 301 generated by the magnet 205.

In the scenario shown in FIG. 2, an operator 209 is prohibited from carrying the object 210 to enter across the edge 207 into the predetermined region 208. The object 210 is, for example, a metal component such as iron. Once a metal component enters the predetermined region 208, there may be safety hazards such as the metal component being attracted onto the magnet 205 or touching a person or object in the examination room.

In some examples, the cameras 201, 202, 203, and 204 are used to acquire a two-dimensional image and a depth image, the images including the edge 207 of at least a portion of the predetermined region 208 around the magnetic resonance imaging device 100. The two-dimensional image is, for example, an RGB image, i.e., an image containing three color channels: red (R), green (G), and blue (B).

In some examples, the cameras 201, 202, 203 and 204 may be installed at different positions around the magnet 205. For example, when the magnetic resonance imaging device 100 is observed from a side, the cameras 201, 202, 203, and 204 may be installed in left front, left rear, right rear, and right front directions of the magnet 205, respectively, so that the field-of-view ranges 201f, 202f, 203f, and 204f of the cameras 201, 202, 203 and 204 can cover the entire predetermined region 208, and by stitching the images acquired by the cameras 201, 202, 203 and 204, an image covering the entire predetermined region 208 can be obtained.

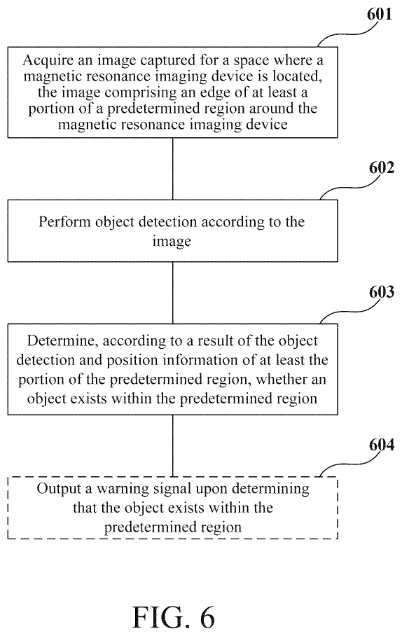

FIG. 6 is a schematic diagram of a method for detecting an object within a predetermined region around a magnetic resonance imaging device according to an embodiment of the present application. The method may use one or more of the cameras 201, 202, 203, and 204 to obtain an image of the edge 207 of the corresponding predetermined region 208 of the magnetic resonance imaging device 100 within a corresponding field of view (for example, the image may be a two-dimensional image, or the image may be a two-dimensional image and a depth image), and determine whether the object 210 exists within the predetermined region 208.

As shown in FIG. 6, the method includes, at step 601, acquiring an image captured for a space where a magnetic resonance imaging device 100 is located, the image comprising an edge 207 of at least a portion of a predetermined region 208 around the magnetic resonance imaging device 100. At step 602, object detection is performed based on the acquired image. At step 603, the method determines, according to the result of the object detection and position information of at least the portion of the predetermined region 208, whether an object 210 exists within the predetermined region 208.

Hence, the present application enables detection of the object 210 within the restricted region 208 around the magnetic resonance imaging device 100, thereby achieving safety monitoring of the environment around the magnetic resonance imaging device 100. Compared to the solution of posting a warning line around a magnetic resonance imaging device, the present application will not affect the environment cleanliness of the magnetic resonance room, and can actively perform detection to effectively prevent an object such as a metal component from entering the predetermined region around the magnetic resonance imaging device (for example, a predetermined magnetic field region).

The method for detecting an object within a predetermined region around a magnetic resonance imaging device of the present application further includes, at step 604, outputting a warning signal upon determining that the object 210 exists within the predetermined region 208.

In some examples, the warning signal may be sent to an alarm device, causing the alarm device to sound an alarm. For example, the warning signal may cause a speaker to emit sound, or cause a display to display predetermined texts and/or patterns, or cause a warning light to flash or illuminate at a certain frequency.

The following describes the method for detecting an object within a predetermined region around a magnetic resonance imaging device according to the present application in conjunction with different embodiments.

### Embodiment 1

Any camera 201, 202, 203, or 204 deployed in the MR examination room acquires a two-dimensional image of the edge 207 of the corresponding predetermined region 208 of the magnetic resonance imaging device 100 within the field of view 201f, 202f, 203f, or 204f thereof. The position of the palm or another body part in the two-dimensional image is estimated, and segmentation is performed with respect to the object 210 to determine whether the object 210 exists within the two-dimensional predetermined region 208. Embodiment 1 is described by using a two-dimensional image captured by the camera 201 as an example.

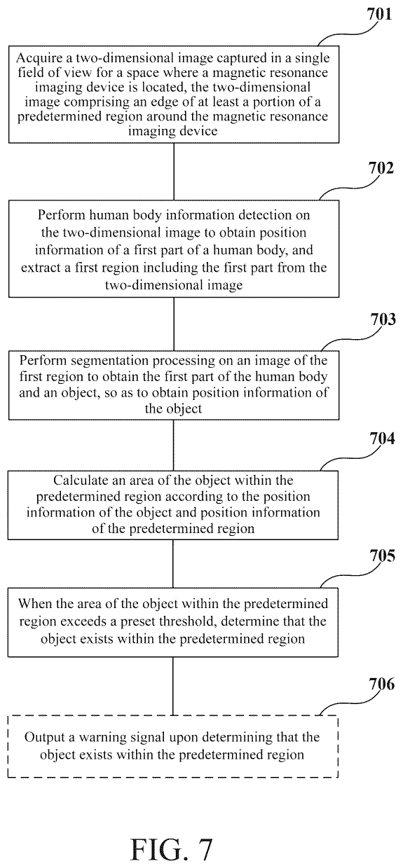

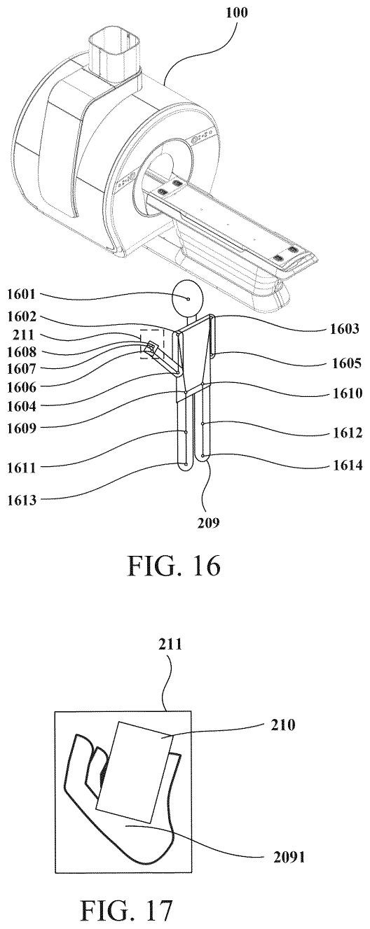

FIG. 7 is a schematic diagram of a method for detecting an object within a predetermined region around a magnetic resonance imaging device according to Embodiment 1 of the present application. FIG. 16 is a schematic diagram of detecting human body information and extracting a first region from a two-dimensional image captured in a single field of view of a space where the magnetic resonance imaging device is located. FIG. 17 is a schematic diagram of an enlarged view of the first region extracted in FIG. 16.

As shown in FIG. 7, the method includes, at step 701, acquiring a two-dimensional image captured in a single field of view corresponding to the space where the magnetic resonance imaging device 100 is located, the two-dimensional image including an edge 207 of at least a portion of a predetermined region 207 around the device 100. At step 702, human body information detection is performed on the two-dimensional image to obtain position information of a first part 2091 of a human body, and a first region 211 including the first part 2091 is extracted from the two-dimensional image. At step 703, segmentation processing is performed on an image of the first region 211 to obtain the first part 2091 of the human body and an object 210, so as to obtain position information of the object 210.

Continuing with FIG. 7, the method includes, at step 704, calculating an area of the object 210 within the predetermined region 208 based on the position information of the object 210 and the position information of the predetermined region 208. At step 705, when the area of the object 210 within the predetermined region 208 exceeds a preset threshold, the method determines that the object 210 exists within the predetermined region 208. Steps 701 through 705 correspond to the detailed process shown in FIG. 7, where step 701 aligns with step 601 in FIG. 6, steps 702 and 703 implement step 602, and steps 704 and 705 implement step 603.

In some examples, at step 702, the human body information detection performed on the image may include human body posture detection. The present application may use a deep learning model (such as a BlazePose model) for human body posture estimation to perform human body posture detection. The detection results of the deep learning model for human body posture estimation may be positions of a plurality of parts of the human body.

For example, during training of the deep learning model for human body posture detection, a plurality of two-dimensional images captured in a single field of view of the space where the magnetic resonance imaging device 100 is located may be used as an input data set, and positions of a plurality of parts of the human body pre-marked in the corresponding two-dimensional images (ground truth) may be used as the ground truth. The deep learning model is trained based on the input data set (unsupervised deep learning) or based on the input data set and the ground truth (supervised deep learning) to obtain a trained (i.e., parameter-optimized) deep learning model. The deep learning model may, for example, include an input layer, a hidden layer, and an output layer, etc. In addition, during inference of human body posture detection, one or more two-dimensional images (i.e., input images) captured in a single field of view for the space where the magnetic resonance imaging device 100 is located are input into the trained deep learning model to obtain position information of a plurality of parts of the human body in each input image, for example, position information of the head, left and right shoulders, left and right elbows, left and right wrists, left and right palms, left and right fingers, left and right hips, left and right knees, left and right ankles, etc.

As shown in FIG. 16, the plurality of parts of the human body obtained by human body posture detection may be represented by a plurality of key points 1601 to 1614. For example, the key point 1601 represents the head, the key points 1602 and 1603 represent the left and right shoulders respectively, the key points 1604 and 1605 represent the left and right elbows respectively, the key point 1606 represents the left wrist, the key point 1607 represents the left fingers, the key point 1608 represents the left palm, the key points 1609 and 1610 represent the left and right buttocks respectively, the key points 1611 and 1612 represent the left and right knees respectively, and the key points 1613 and 1614 represent the left and right ankles respectively.

In addition, the present application is not limited thereto, and human body information detection may be performed on the two-dimensional image using other models or other methods.

At step 702, the position information of the first part of the human body may be obtained based on a detection result of the human body information detection (e.g., human body posture detection). For example, the detection result of the human body posture detection includes the position information of the first part (for example, the palm), and thus, the position information of the first part may be directly obtained from the detection result of the human body posture detection. For another example, the detection result of the human body posture detection includes position information of another part (e.g., the wrists or fingers) adjacent to the first part (e.g., the palm), and therefore the position information of the first part may be estimated according to a relative position relationship between the adjacent other part and the first part.

At step 702, the first region in the two-dimensional image may be extracted based on the position information of the first part. For example, the first region is a region centered at the position of the first part and having a predetermined shape and a predetermined size.

For example, as shown in FIG. 17, the first part 2091 may be the palm, and the first region 211 is extracted from the two-dimensional image according to detected position information of the palm.

For another example, the first part 2091 may also be another body part that carries the object 210, such as the back, shoulders, elbows, head, etc. For example, the object 210 may be carried on the back, on the shoulder, across the body, or worn on the body.

In some examples, at step 703, the segmentation method may include a threshold, edge, region, or model-based method. For example, in the threshold-based image segmentation method, the intensity or grayscale of each pixel in the image may be compared with a threshold. Pixels with values greater than the threshold are considered to be of the same object, or pixels with values less than a threshold are considered to be of the same object, thereby segmenting the image into a plurality of objects. This method may include a global thresholding method and a variable thresholding method.

In the region-based image segmentation method, distribution characteristics of pixels in the image may be analyzed, thereby dividing the pixels in the image into different regions to segment the image into a plurality of objects. This method includes region growing, region separation and aggregation, etc.

The edge-based segmentation method uses an edge detection algorithm to detect discontinuous brightness parts in the image as edges of adjacent objects, thereby segmenting the image into a plurality of objects by using the edges.

The model-based segmentation method may use a trained model to segment the image into a plurality of objects. The model includes a fully convolutional network (FCN) model, a semantic segmentation network (SegNet) model, a mask region-based convolutional neural network (Mask R-CNN) model, etc.

Through step 703, the position information of the object 210 located within the first region in the two-dimensional image is obtained. The position information includes, for example, positions of the pixels corresponding to the object 210 in the two-dimensional image. The position information can reflect both the position of the object 210 in the two-dimensional image and the area of the object 210 in the two-dimensional image.

In some examples, at step 704, the position of the predetermined region 208 in the captured image may be set in advance according to the position of a camera that captured the image. For example, in two-dimensional images captured by cameras at different positions, positions or shapes of the predetermined region 208 in the images may be different.

At step 704, based on the position information of the object 210 and the position information of the predetermined region 208 obtained in step 703, it may be determined whether the object 210 and the predetermined region 208 have an overlapping portion. If an overlapping portion exists, an area of the overlapping portion (for example, the number of pixels corresponding to the overlapping portion) is calculated, where the overlapping portion is a portion of the object 210 located within the predetermined region 208.

At step 705, it is determined whether the area of the overlapping portion exceeds a preset threshold. If the area of the overlapping portion exceeds the preset threshold, it is determined that the object 210 exists within the predetermined region 208. If the area of the overlapping portion does not exceed the preset threshold or the overlapping portion does not exist, it is determined that the object 210 does not exist within the predetermined region 208.

FIG. 13 is a schematic diagram of a camera calibration tool according to an embodiment of the present application. In some examples, calibration processing may be performed on the camera 201. For example, a calibration mark is set at a predetermined position on the examination table 206. The calibration mark is, for example, a checkerboard 1301 (as shown in FIG. 13), and calibration processing is performed based on the calibration mark.

There are many methods to perform the calibration processing. For example, in one method, the angle and position of the camera 201 may be adjusted, and the calibration is completed when the position of the checkerboard 1301 in the image captured by the camera 201 is located at a preset position. For another example, in another method, the coordinates of the checkerboard 1301 in the image captured by the camera 201 (i.e., the coordinates in an image coordinate system) are determined. In conjunction with predetermined coordinates of the checkerboard 1301 in a coordinate system of the magnetic resonance imaging device 100 (e.g., a position of the checkerboard 1301 on the examination table 206 is predetermined, and therefore, the coordinates of the checkerboard 1301 in the coordinate system of the magnetic resonance imaging device 100 are also predetermined), a mapping relationship between the image coordinate system and the coordinate system of the magnetic resonance imaging device 100 may be determined (e.g., the coordinates in the image coordinate system may be converted into the coordinate system of the magnetic resonance imaging device 100 through a translation operation or a rotation operation). Thus, the position of a person or an object in the image captured by the camera 201, once determined, can be converted into a position in the coordinate system of the magnetic resonance imaging device 100, thereby easily determining a relative positional relationship between the person or object in the image and the predetermined region 208.

The above description merely uses the calibration of the camera 201 as an example. For calibration processing of the camera 202, 203, or 204, reference may also be made to this method.

In some examples, the method for detecting an object within a predetermined region around a magnetic resonance imaging device according to Embodiment 1 of the present application further includes, at step 706, outputting a warning signal upon determining that the object 210 exists within the predetermined region 208.

### Embodiment 2

Any camera 201, 202, 203, or 204 deployed in the MR examination room acquires a two-dimensional image and a depth image of the edge 207 of the predetermined region 208 around the magnetic resonance imaging device 100 in the field of view 201f, 202f, 203f or 204f thereof. The position of the palm or another body part that may carry the object 210 in the two-dimensional image is estimated, and segmentation is performed with respect to the object 210 in conjunction with information of the two-dimensional image and the depth image, so as to determine whether the object 210 exists within the two-dimensional region 208. Embodiment 2 is described by using an example in which the image captured by the camera 201 includes a two-dimensional image and a depth image.

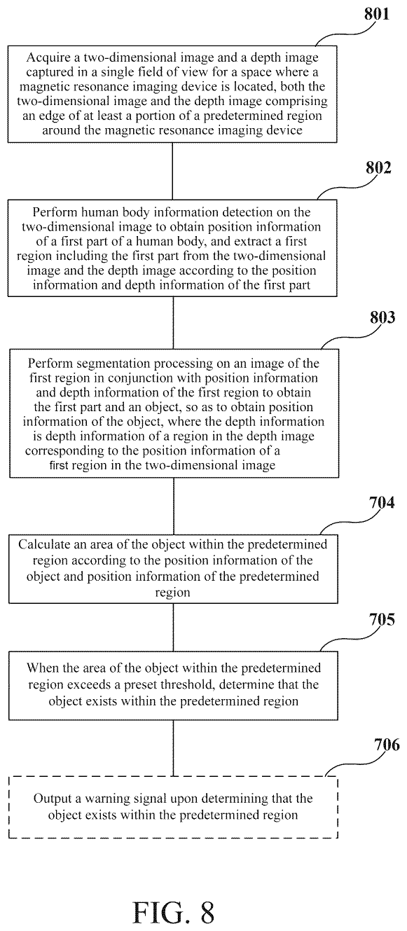

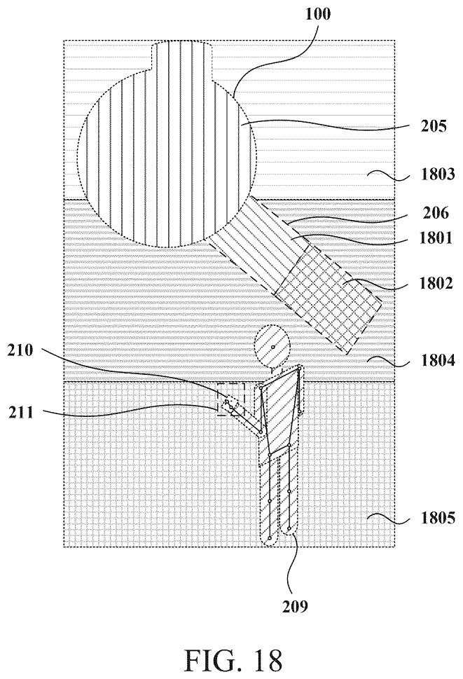

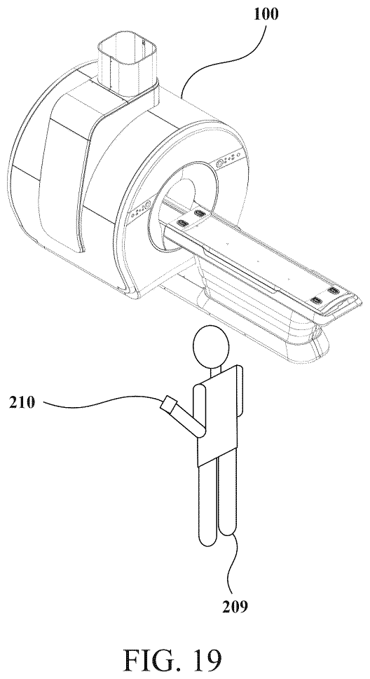

FIG. 8 is a schematic diagram of a method for detecting an object within a predetermined region around a magnetic resonance imaging device according to Embodiment 2 of the present application. FIG. 18 is a schematic diagram in which results of the human body information detection and the first region extraction in FIG. 16 are mapped to a depth image in the same field of view. FIG. 19 is a schematic diagram of a result of segmentation performed in conjunction with the information of the two-dimensional image and the depth image.

As shown in FIG. 8, the method includes steps 704, 705, and 706 as shown in FIG. 7, and further includes, at step 801, acquiring a two-dimensional image and a depth image captured in a single field of view for a space where a magnetic resonance imaging device 100 is located, both the two-dimensional image and the depth image comprising an edge 207 of at least a portion of a predetermined region 208 around the magnetic resonance imaging device 100.

At step 802, human body information detection is performed on the two-dimensional image to obtain position information of a first part 2091 of a human body, and a first region 211 including the first part 2091 is extracted from the two-dimensional image and the depth image according to the position information and depth information of the first part 2091. Compared with step 702 in Embodiment 1, extracting the first region 211 in conjunction with the position information and the depth information of the first part 2091 can improve the accuracy of extracting the first region 211.

At step 803, segmentation processing is performed on an image of the first region 211 in conjunction with position information and depth information of the first region 211 to obtain the first part 2091 and an object 210, so as to obtain position information of the object 210, where the depth information is depth information of a region in the depth image corresponding to the position information of the first region 211 in the two-dimensional image.

Step 801 corresponds to step 601 in FIG. 6, steps 802 and 803 are used to implement step 602.

As shown in FIG. 18, in the depth image, a depth value of each object varies according to a distance between the object and the camera 201 that captures the depth image. For example, a depth region of the space where the magnetic resonance imaging device 100 is located may be schematically divided into regions 1803, 1804, and 1805, which are arranged as 1803, 1804, and 1805 in sequence in descending order according to distances from the camera 201 that captures the depth image. A depth region of the examination table 206 of the magnetic resonance imaging device 100 may be schematically divided into 1801 and 1802. The parts of the magnetic resonance imaging device 100 are arranged in descending order of distances from the camera 201 that captures the depth image as follows: the magnet 205 of the magnetic resonance imaging device 100, the region 1801 of the examination table 206, and the region 1802 of the examination table 206. The depth of the operator 209 and the depth of the object 210 carried by the operator 209 correspond to different regions respectively, such that segmentation with respect to the first part 2091 of the operator 209 and the object 210 can be performed by processing the depth values.

In some examples, the length and width of the two-dimensional image may be (l, w), and the position information of the first region 211 in the image may be a region with the center coordinates of (x0, y0) and a length and width of (l0, w0), i.e., a region [x0−w0/2: x0+w0/2, y0-l0/2:y0+l0/2], where x0-w0/2≥1, x0+w0/2≤w, y0-l0/2≥1, y0+l0/2≤l; the length and width of the depth image may be (l, w), which is the same as the length and width of the two-dimensional image. In this case, the position of the first region 211 in the depth image may be a region with the center coordinates of (x0, y0) and a length and width of (l0, w0), and the depth information of the first region 211 may serve as depth information of said region.

In some examples, normalization of the depth image may include methods such as outlier removal, hole filling, and depth value mapping. Among them, the outlier removal method detects outliers in the image and deletes or replaces the outliers; typical methods include clustering, isolation forest, and support vector machine, etc. The hole filling method includes nearest neighbor interpolation, bilinear interpolation, and bicubic difference, etc. The depth value mapping method may, for example, normalize depth values to a range of 800 to 5000, thereby adapting to an optimal working range of the camera and improving the stability of a subsequent image processing algorithm.

In some examples, at step 803, the segmentation method includes segmenting the two-dimensional image and the depth image respectively to obtain the first part 2091 and the object 210, or segmenting a three-dimensional image, which is obtained by fusing the two-dimensional image and the depth image, to obtain the first part 2091 and the object 210. The position of the object 210 obtained by segmentation is shown in FIG. 19. Both methods utilize depth image information to perform object segmentation more accurately, thereby improving the accuracy of object detection.

For example, at step 803, the segmentation method may include segmenting the two-dimensional image and the depth image respectively to obtain the first part 2091 and the object 210, so as to obtain a segmentation result for the first part 2091 and the object 210 in the two-dimensional image and a segmentation result for the first part 2091 and the object 210 in the depth image, and fuse the two segmentation results (for example, taking an intersection of the position information of the object 210 contained in the two segmentation results) to obtain the position information of the object 210. The segmentation method for the two-dimensional image may be the same as the segmentation method at step 703 in Embodiment 1. The segmentation method for the depth image may adopt a method based on depth value differences and an 8-connected component. For example, adjacent pixels in the depth image whose depth value differences are within a threshold constitute a connected component (where the connected component is an 8-connected component), and the connected component is used as a segmentation boundary for different objects in the image or is used as an object in the image, thereby segmenting the image into a plurality of objects. In addition, a deep learning model may also be used to segment the depth image. For example, during training of the deep learning model, a plurality of depth images may be used as an input data set, and position information (ground truth) of objects pre-marked in corresponding depth images may be used as the ground truth. The deep learning model is trained based on the input data set (unsupervised deep learning) or based on the input data set and the ground truth (supervised deep learning), to obtain a trained (i.e., parameter-optimized) deep learning model. In addition, during inference for image segmentation, one or more depth images (i.e., input images) captured for the space where the magnetic resonance imaging device 100 is located in a single field of view are input into the trained deep learning model to obtain position information of the object in each input image.

For another example, at step 803, the segmentation method may include segmenting the three-dimensional image, which is obtained by fusing the two-dimensional image and the depth image, to obtain the first part 2091 and the object 210, so as to obtain a segmentation result for the first part 2091 and the object 210 in the three-dimensional image, thereby obtaining the position information of the object 210. For example, the three-dimensional image has depth value information. Hence, segmentation can be performed by using a method based on depth value differences and a 8-connected component, or by using a deep learning model.

### Embodiment 3

Two or more cameras deployed in the MR examination room capture two-dimensional images of the edge 207 of the predetermined region 208 around the magnetic resonance imaging device 100 within the field-of-view ranges 201f, 202f, 203f, and 204f thereof, and the various two-dimensional images are fused into a three-dimensional image to determine whether the object 210 exists within the predetermined region 208. Embodiment 3 is described by using two-dimensional images captured by the cameras 201, 202, 203, and 204 as an example.

In some embodiments, two or more images are acquired, which correspond to two or more different fields of view, for example, corresponding to the field-of-view ranges 201f, 202f, 203f, and 204f.

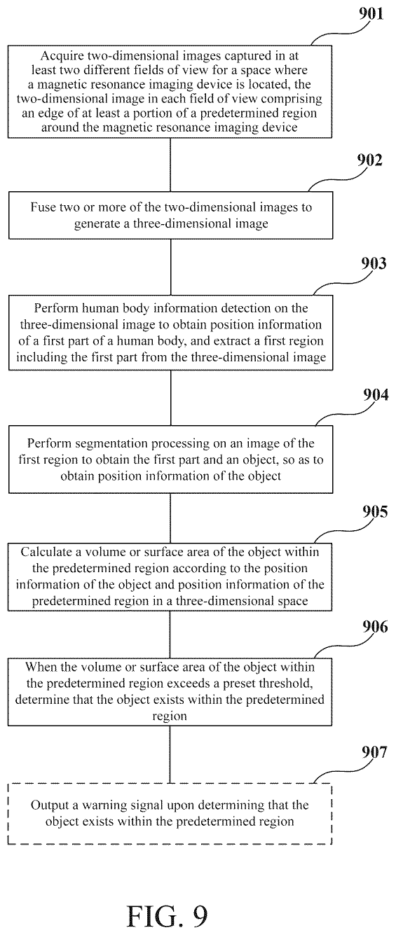

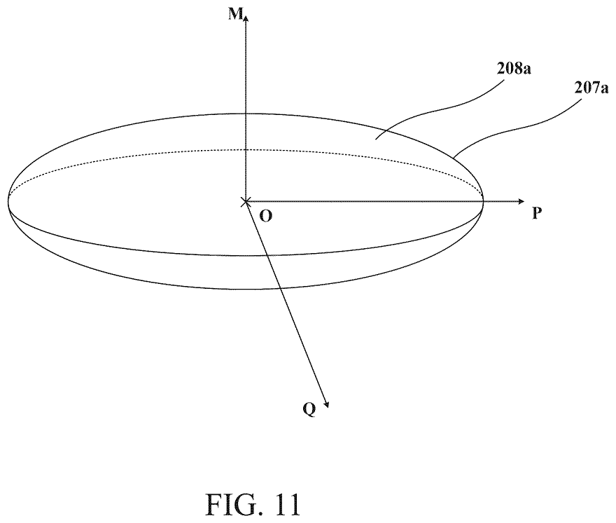

FIG. 9 is a schematic diagram of a method for detecting an object within a predetermined region around a magnetic resonance imaging device according to Embodiment 3 of the present application. FIG. 11 is a schematic diagram of a three-dimensional fringe field of magnet of a magnet of a magnetic resonance imaging device according to an embodiment of the present application.

As shown in FIG. 9, the method includes, at step 901, acquiring two-dimensional images captured in at least two different fields of view for a space where a magnetic resonance imaging device 100 is located, where the two-dimensional image in each field of view includes an edge 207 of at least a portion of a predetermined region 208 around the magnetic resonance imaging device 100.

At step 902, two or more of the two-dimensional images are fused to generate a three-dimensional image.

At step 903, human body information detection is performed on the three-dimensional image to obtain position information of a first part 2091 of a human body, and a first region 211 including the first part 2091 is extracted from the three-dimensional image.

At step 904, segmentation processing is performed on an image of the first region 211 to obtain the first part 2091 and an object 210, so as to obtain information of the object 210.

At step 905, a volume or surface area of the object 210 within the predetermined region 208a is calculated according to the position information of the object 210 and position information of the predetermined region 208a in a three-dimensional space.

At step 906, when the volume or surface area of the object 210 within the predetermined region 208a exceeds a preset threshold, the method determines that the object 210 exists within the predetermined region 208a.

Step 901 corresponds to step 601 in FIG. 6, steps 903 and 904 are used to implement step 602, and steps 905 and 906 are used to implement step 603.

In some examples, at step 902, the two-dimensional images captured by the cameras 201, 202, 203, and 204 are fused, and a method such as feature point matching, image registration, and image fusion may be used to generate a three-dimensional image covering an edge 207a of the entire predetermined region 208a of the magnetic resonance imaging device 100.

In some examples, at step 903, the human body information detection performed on the three-dimensional image may be human body posture detection. The present application may use a deep learning model for human body posture estimation (such as a BlazePose model) to perform the human body posture detection. The detection result of the deep learning model for human body posture estimation may be the positions of a plurality of parts of the human body in the three-dimensional space.

For example, during training of the deep learning model for human body posture detection based on three-dimensional images, a plurality of three-dimensional images covering the space where the magnetic resonance imaging device 100 is located may be used as an input data set, and position information (ground truth) of a plurality of parts of the human body pre-marked in the corresponding three-dimensional images may be used as the ground truth. The deep learning model is trained based on the input data set (unsupervised deep learning) or based on the input data set and the ground truth (supervised deep learning) to obtain a trained (i.e., parameter-optimized) deep learning model. The deep learning model may, for example, include an input layer, a hidden layer, and an output layer. In addition, during inference of human body posture detection, one or more three-dimensional images (i.e., input images) covering the space where the magnetic resonance imaging device 100 is located are input into the trained deep learning model to obtain position information of a plurality of parts of the human body in each input image in the three-dimensional space, for example, position information of the head, left and right shoulders, left and right elbows, left and right wrists, left and right palms, left and right fingers, left and right hips, left and right knees, left and right ankles, etc.

In addition, the present application is not limited thereto, and human body information detection may be performed on the three-dimensional image using other models or other methods.

At step 903, the position information of the first part of the human body in the three-dimensional space may be obtained based on the detection result of human body information detection (e.g., human body posture detection). For example, the detection result of the human body posture detection includes the position information of the first part (for example, the palm), and thus, the position information of the first part may be directly obtained from the detection result of the human body posture detection. For another example, the detection result of human body posture detection includes position information of another part (e.g., the wrists or fingers) adjacent to the first part (e.g., the palm), and therefore the position information of the first part may be estimated according to a relative position relationship between the adjacent other part and the first part.

At step 903, the first region in the three-dimensional image may be extracted based on the position information of the first part. For example, the first region is a spatial region centered at the position of the first part and having a predetermined shape and a predetermined size.

In some examples, at step 903, the first region 211 may include a three-dimensional image.

In some examples, at step 904, the information of the object 210 may be three-dimensional information, for example, including position information and volume information.

In some examples, at step 905, the position of the predetermined region 208a in the synthesized 3D image may be set in advance according to the positions of the cameras that capture the two-dimensional images synthesized into the three-dimensional image.

At step 905, based on the position information of the object 210 obtained in step 904 and the position information of the predetermined region 208a in the three-dimensional space, it may be determined whether the object 210 and the predetermined region 208 have any overlapping portion, and if there is an overlapping portion, the volume (for example, the number of pixels corresponding to the overlapping portion) or surface area (for example, the number of pixels corresponding to an edge of the overlapping portion) of the overlapping portion is calculated, where the overlapping portion is a portion of the object 210 located within the predetermined region 208a.

In some examples, the predetermined region 208a is ellipsoidal in the three-dimensional space, and the edge 207a thereof is an outer surface of the ellipsoid, as shown in FIG. 11. The center O of the magnet is located at the coordinate origin (0, 0, 0). A P direction is a direction pointing to the top and bottom of the body in an anatomical coordinate system, for example, consistent with the direction of extension of the examination table, also known as an S/I direction. A Q direction is a direction pointing to the left and right sides of the body in the anatomical coordinate system, for example, perpendicular to the direction of extension of the examination table and parallel to a horizontal direction, also known as an R/L direction. An M direction is a direction pointing to the front and back of the body in the anatomical coordinate system, for example, parallel to a vertical direction, also known as an A/P direction.

In some examples, at step 906, when the volume or surface area of the object 210 within the predetermined region 208a exceeds the preset threshold, it is determined that the object 210 exists within the predetermined region 208a.

The two-dimensional region 208 when mapped to a three-dimensional space has a cylindrical shape, while the three-dimensional region 208a has an ellipsoidal shape and can truly reflect a spatial distribution of the fringe field of magnet; accordingly, using the three-dimensional region 208a as the determination basis can more accurately determine whether the object 210 enters the restricted region.

In some examples, the method for detecting an object within a predetermined region around a magnetic resonance imaging device according to Embodiment 3 of the present application further includes at step 907 outputting a warning signal upon determining that the object 210 exists within the predetermined region 208a.

### Embodiment 4

Two or more cameras deployed in the MR examination room, such as the cameras 201, 202, 203 and 204, capture two-dimensional images and depth images of the edge 207 of the predetermined region 208 around the magnetic resonance imaging device 100 within the field-of-view ranges 201f, 202f, 203f, and 204f thereof, and the various two-dimensional images and depth images are fused into a three-dimensional image to determine whether the object 210 exists within the predetermined region 208a.

In some embodiments, the acquired images further include depth images corresponding to the two-dimensional images. For example, the camera 201 simultaneously acquires a two-dimensional image and a depth image within the field of view 201f, and the remaining cameras 202, 203, and 204 acquire images in the same way as the camera 201.

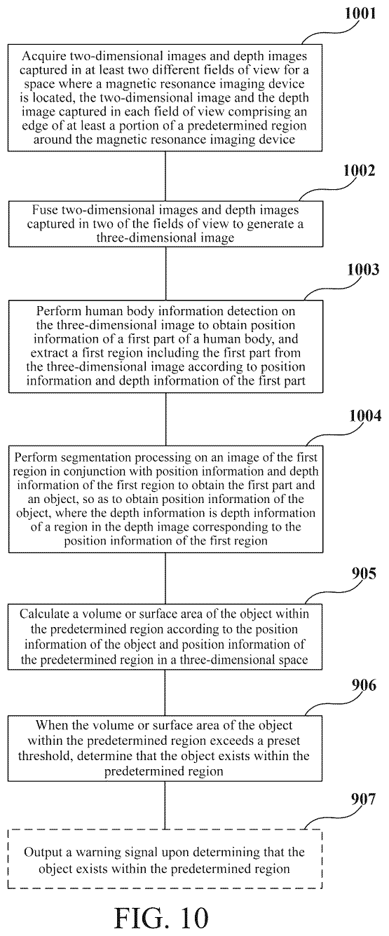

FIG. 10 is a schematic diagram of a method for detecting an object within a predetermined region around a magnetic resonance imaging device according to Embodiment 4 of the present application.

As shown in FIG. 10, the method includes steps 905, 906, and 907 as shown in FIG. 9, and further includes, at step 1001, acquiring two-dimensional images and depth images captured in at least two different fields of view for a space where a magnetic resonance imaging device 100 is located, where the two-dimensional image and the depth image captured in each field of view comprise an edge 207 of at least a portion of a predetermined region 208 around the magnetic resonance imaging device 100.

At step 1002, two-dimensional images and depth images captured in two or more of the fields of view are fused to generate a three-dimensional image.

At step 1003, human body information detection is performed on the three-dimensional image to obtain position information of a first part 2091 of a human body, and a first region 211 including the first part 2091 is extracted from the three-dimensional image according to position information and depth information of the first part 2091.

At step 1004, segmentation processing is performed on an image of the first region 211 in conjunction with position information and depth information of the first region 211 to obtain the first part 2091 and an object 210, so as to obtain position information of the object 210, where the depth information is depth information of a region in the depth image corresponding to the position information of the first region 211.

In some examples, depth image normalization processing as described in Embodiment 2 is performed on the depth image in each field of view.

At step 1004 of Embodiment 4, the information of the depth image can be used to more accurately perform segmentation with respect to the object, thereby improving the accuracy of object detection.

### Embodiment 5

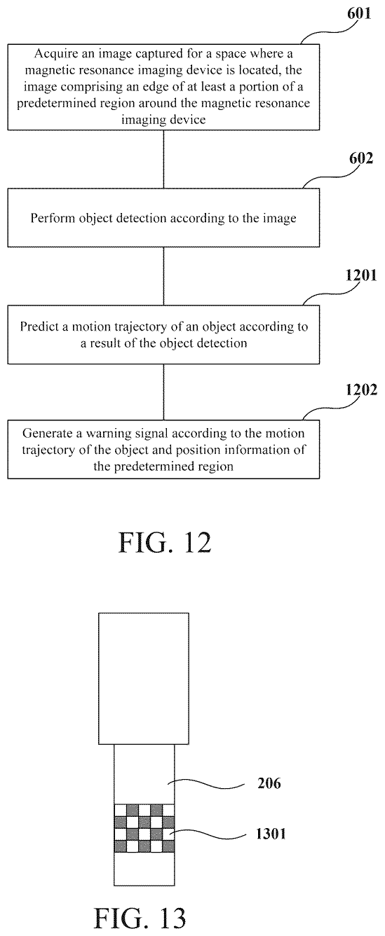

This embodiments of the present application further provide a method for predicting a motion trajectory of the object 210. FIG. 12 is a schematic diagram of a method for predicting an object motion trajectory according to an embodiment of the present application.

As shown in FIG. 12, the method includes steps 601 and 602 as shown in FIG. 6, and further includes, at step 1201, predicting a motion trajectory of an object 210 according to a result of the object detection.

At step 1202, generating a warning signal according to the motion trajectory of the object 210 and position information of the predetermined region 208.

In some examples, at step 1201, the position information of the object 210 over a period of time is processed to predict position information and a movement speed of the object 210 at a next moment, and a plurality of pieces of predicted position information are connected in series in chronological order to form a predicted motion trajectory. For example, a Kalman filtering (KF) method may be used to predict the motion trajectory of the object.

In some examples, at step 1202, when the direction of the motion trajectory of the object 210 is toward the predetermined region 208 and the distance between the object 210 and the predetermined region 208 is less than a threshold, a warning signal is generated. Therefore, even if the object 210 does not enter the predetermined region 208, prediction and warning can be performed in advance, thereby further improving safety.

In the present application, the method shown in FIG. 12 and the method shown in FIG. 6 can be performed in parallel. For example, steps 601 and 602 are performed, and then step 603 is performed using the object detection result of step 602 to determine whether the object exists 210 in the predetermined region 208. At the same time, steps 1201 and 1202 are performed using the object detection result of step 602 to determine whether the object 210 is moving toward the predetermined region 208.

The above embodiments merely provide illustrative descriptions of the embodiments of the present application. However, the present application is not limited thereto, and suitable variations may be made on the basis of the above embodiments. For example, each of the above embodiments may be used independently, or one or more of the above embodiments may be combined.

### Embodiments of Second Aspect

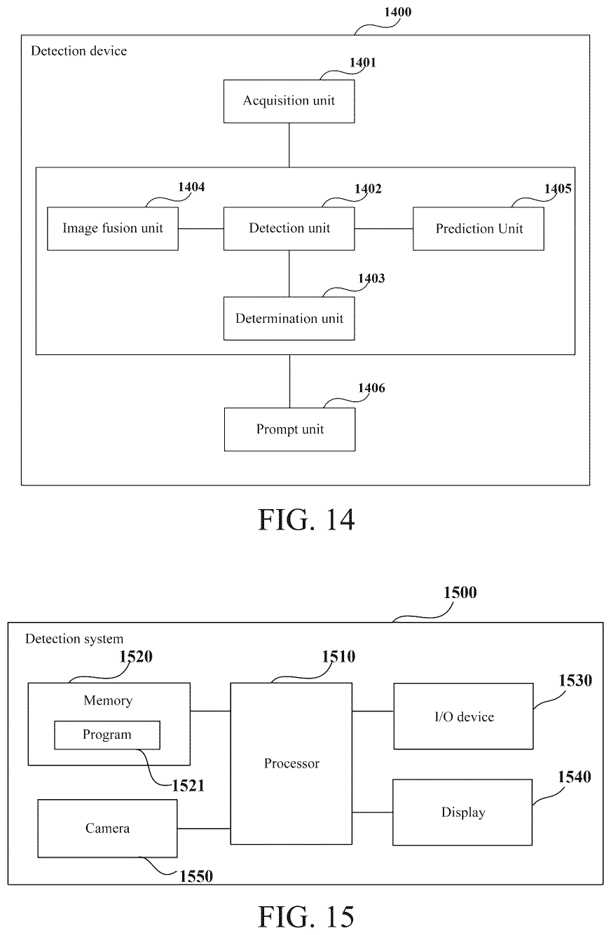

The embodiments of the second aspect of the present application provide an apparatus for detecting an object within a predetermined region around a magnetic resonance imaging device. FIG. 14 is a schematic diagram of an apparatus for detecting an object within a predetermined region around a magnetic resonance imaging device according to an embodiment of the present application. As shown in FIG. 14, the detection apparatus 1400 includes:
an acquisition unit 1401, configured to acquire an image captured for a space where a magnetic resonance imaging device 100 is located, the image comprising an edge 207 of at least a portion of a predetermined region 208 around the magnetic resonance imaging device 100;
a detection unit 1402, configured to perform object detection according to the image; and
a determination unit 1403, configured to determine, according to a result of the object detection and position information of at least the portion of the predetermined region 208, whether an object 210 exists within the predetermined region 208.

In some embodiments, the image acquired by the acquisition unit 1401 includes a two-dimensional image.

The detection unit 1402 performing object detection on the image includes:
performing human body information detection according to the image to obtain position information of a first part 2091 of a human body, and extracting a first region 211 including the first part 2091 from the captured image; and
performing segmentation processing on an image of the first region 211 to obtain the first part 2091 and the object 210, so as to obtain position information of the object 210.

In some embodiments, the image acquired by the acquisition unit 1401 further includes a depth image. The detection unit 1402 performs segmentation processing on the image of the first region 211 in conjunction with the position information and depth information of the first part 2091 to obtain the first part 2091 and the object 210, so as to obtain the position information of the object 210, where the depth information is depth information of a region in the depth image corresponding to the first region 211.

In some embodiments, the determination unit 1403 determining, according to a result of the object detection and position information of at least the portion of the predetermined region 208, whether the object 210 exists within the predetermined region 208 includes:
the determination unit 1403 calculating, according to the position information of the object 210 and position information of the predetermined region 208, an area of the object 208 within the predetermined region 208; and
when the area of the object 210 within the predetermined region 208 exceeds a preset threshold, determining that the object 210 exists within the predetermined region 208.

In some embodiments, the acquisition unit 1401 acquires two or more images, which correspond to two or more different fields of view.

In some embodiments, the image acquired by the acquisition unit 1401 includes two-dimensional images, and the apparatus 1400 further includes an image fusion unit 1404 that fuses two or more of the two-dimensional images to generate a three-dimensional image.

The detection unit 1402 detecting the object 210 includes:
performing human body information detection on the three-dimensional image to obtain position information and depth information of the first part 2091 of the human body, and extracting the first region 211 including the first part 2091 from the three-dimensional image; and
performing segmentation processing on an image of the first region 211 to obtain the first portion 2091 and the object 210, so as to obtain information of the object 210.

In some embodiments, the image acquired by the acquisition unit 1401 also includes a depth image corresponding to each two-dimensional image. According to depth information of a region in the depth image corresponding to the first region 211, the detection unit 1402 performs segmentation processing on the image of the first region 211 to obtain the first part 2091 and the object 210, so as to obtain information of the object 210.

In some embodiments, the determination unit 1403 determining, according to the detection result of the object 210 and position information of at least the portion of the predetermined region 208a, whether the object 210 exists within the predetermined region 208a includes:
the determination unit 1403 calculating, according to the position information of the object 210 and the information of the predetermined region 208a in the three-dimensional image, a volume or surface area of the object 210 within the predetermined region 208a; and when the volume or surface area of the object 208 within the predetermined region 208a exceeds a preset threshold, determining that the object 210 exists within the predetermined region 208a.

In some embodiments, the apparatus 1400 further includes:
a prediction unit 1405, configured to predict a motion trajectory of the object 210 according to the result of the object detection;
a prompt unit 1406, configured to generate a warning signal according to the motion trajectory of the object 210 and position information of the predetermined region 208 or 208a.

### Embodiments of Third Aspect

The embodiments of the present application further provide a system 1500 for detecting an object within a predetermined region around a magnetic resonance imaging device, and include performing the method for detecting an object within a predetermined region around a magnetic resonance imaging device according to the first aspect, the content of which is incorporated herein. The system may have, for example, a computer, a server, a workstation, a laptop, a smartphone, etc. However, the embodiments of the present application are not limited thereto.

FIG. 15 is a schematic diagram of a system for detecting an object within a predetermined region around a magnetic resonance imaging device according to an embodiment of the present application. As shown in FIG. 15, the detection system 1500 may include: one or more processors (for example, central processing units (CPUs)) 1510 and one or more memories 1520. The memory 1520 is coupled to the processor 1510. The memory 1520 may store various types of data. In addition, the memory further stores a program 1521 for information processing, and executes the program 1521 under the control of the processor 1510.

In some embodiments, the method for detecting the object 210 within the predetermined region 208 around the magnetic resonance imaging device 100 is integrated into the processor 1510. The processor 1510 is configured to implement the method for detecting the object 210 within the predetermined region 208 around the magnetic resonance imaging device 100 according to the above embodiments of the present application.

In some embodiments, a program for executing the method for detecting the object 210 within the predetermined region 208 around the magnetic resonance imaging device 100 may be burned onto a chip connected to the processor 1510, and the method for detecting the object 210 within the predetermined region 208 around the magnetic resonance imaging device 100 of the above embodiments may be implemented under the control of the processor 1510.

For example, the processor 1510 is configured to perform the following control: acquiring an image captured by a camera for a space where the magnetic resonance imaging device 100 is located; determining, based on the image, whether the object 210 exists within the predetermined region 208 around the magnetic resonance imaging device 100; and outputting information related to a result of the determination.

In a specific example, the detection system 1500 of FIG. 15 may be the magnetic resonance imaging (MRI) system 100 shown in FIG. 1. The memory 1520 of FIG. 15 may correspond to at least one of the memory 137 and the memory 126 of FIG. 1. For example, the memory 1520 may be independent of at least one of the memory 137 and the memory 126, or the memory 1520 may be in communication with at least one of the memory 137 and the memory 126, or the memory 1520 may include at least one of the memory 137 and the memory 126, etc. The processor 1510 of FIG. 15 may correspond to at least one of the CPU 131, the CPU 124, and the image processor 128 of FIG. 1. For example, the processor 1510 may be independent of at least one of the CPU 131, the CPU 124, and the image processor 128, or the processor 1510 may be in communication with at least one of the CPU 131, the CPU 124, and the image processor 128, or the processor 1510 may include at least one of the CPU 131, the CPU 124, and the image processor 128, etc.

In addition, as shown in FIG. 15, the detection system 1500 may further include: an input/output (I/O) device 1530, a display 1540, etc. The functions of the foregoing components are similar to those in the prior art. Details are not described herein again.

In addition, as shown in FIG. 15, the detection system 1500 may further include a camera 1550, which may be at least one of the cameras 201, 202, 203, or 204 in the application scenario shown in FIG. 2. The camera captures an image for the magnetic resonance imaging device 100. The image may be transmitted to the processor 1510, such that the processor 1510 can implement the method for detecting the object 210 within the predetermined region 208 around the magnetic resonance imaging device 100 according to the above embodiments of the present application based on the image captured by the camera 1550.

It is worth noting that the detection system 1500 does not necessarily have to include all the components shown in FIG. 15. In addition, the detection system 1500 may further include components not shown in FIG. 15, and reference may be made to related technologies.

The embodiments of the present application further provide a computer-readable program, where when the program is executed in a medical imaging system, the program causes the computer to perform the method for detecting the object 210 within the predetermined region 208 around the magnetic resonance imaging device 100 according to the above embodiments in the detection system 1500.

The embodiments of the present application further provide a storage medium storing a computer-readable program, where the computer-readable program causes a computer in the detection system 1500 to perform the method for detecting the object 210 within the predetermined region 208 around the magnetic resonance imaging device 100 according to the above embodiments.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a disk, an optical disk, a DVD, a flash memory, etc.

The method/apparatus described in view of the embodiments of the present application may be directly embodied as hardware, a software module executed by a processor, or a combination of the two. For example, one or more of the functional block diagrams and/or one or more combinations of the functional block diagrams shown in the drawings may correspond to either respective software modules or respective hardware modules of a computer program flow. The foregoing software modules may respectively correspond to the steps shown in the figures. The foregoing hardware modules can be implemented, for example, by firming the software modules using a field-programmable gate array (FPGA).

The software modules may be located in a RAM, a flash memory, a ROM, an EPROM, an EEPROM, a register, a hard disk, a portable storage disk, a CD-ROM, or any other form of storage medium known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, the software modules can be stored in the MEGA-SIM card or the large-capacity flash memory apparatus.

One or more of the functional blocks and/or one or more combinations of the functional blocks shown in the accompanying drawings may be implemented as a general-purpose processor, a digital signal processor (DSP), an application-specific integrated circuit (ASIC), a field-programmable gate array (FPGA) or other programmable logic devices, discrete gate or transistor logic devices, a discrete hardware assembly, or any appropriate combination thereof for implementing the functions described in the present application. The one or more functional blocks and/or the one or more combinations of the functional blocks shown in the accompanying drawings may also be implemented as a combination of computing devices, such as a combination of a DSP and a microprocessor, multiple microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A method for detecting an object within a predetermined region around a magnetic resonance imaging device, characterized in that the method comprises:
acquiring an image captured for a space where the magnetic resonance imaging device is located, the image comprising an edge of at least a portion of the predetermined region around the magnetic resonance imaging device;
performing object detection according to the image; and
determining, according to a result of the object detection and position information of at least the portion of the predetermined region, whether the object exists within the predetermined region.

2. The method according to claim 1, wherein the image comprises a two-dimensional image, and
the performing object detection according to the image comprises:
performing human body information detection on the image to obtain position information of a first part of a human body, and extracting a first region comprising the first part from the two-dimensional image; and
performing segmentation processing on an image of the first region to obtain the first part and the object, so as to obtain position information of the object.

3. The method according to claim 2, wherein the image further comprises a depth image, and
segmentation processing is performed on the image of the first region in conjunction with position information and depth information of the first region to obtain the first part and the object, so as to obtain the position information of the object,
wherein the depth information is depth information of a region in the depth image corresponding to the first region.

4. The method according to claim 2, wherein the determining, according to a result of the object detection and position information of at least the portion of the predetermined region, whether the object exists within the predetermined region comprises:
calculating, according to the position information of the object and position information of the predetermined region, an area of the object within the predetermined region; and
when the area of the object within the predetermined region exceeds a preset threshold, determining that the object exists within the predetermined region.

5. The method according to claim 1, wherein two or more images are acquired, and respectively correspond to two or more different fields of view.

6. The method according to claim 5, wherein the image comprises two-dimensional images, and
detecting the object comprises:
fusing two or more of the two-dimensional images to generate a three-dimensional image;
performing human body information detection on the three-dimensional image to obtain position information of a first part of a human body, and extracting a first region comprising the first part from the three-dimensional image; and
performing segmentation processing on an image of the first region to obtain the first part and the object, so as to obtain information of the object.

7. The method according to claim 6, wherein the image further comprises a depth image corresponding to each of the two-dimensional images, and
segmentation processing is performed on the image of the first region in conjunction with position information and depth information of the first region to obtain the first part and the object, so as to obtain the information of the object, wherein the depth information is depth information of a region in the depth image corresponding to the first region.

8. The method according to claim 6, wherein the determining, according to a result of the object detection and position information of at least the portion of the predetermined region, whether the object exists within the predetermined region comprises:
calculating, according to the position information of the object and position information of the predetermined region in the three-dimensional image, a volume or surface area of the object within the predetermined region, and when the volume or surface area of the object within the predetermined region exceeds a preset threshold, determining that the object exists within the predetermined region.

9. The method according to claim 1, wherein the method further comprises:
predicting a motion trajectory of the object according to the result of the object detection; and
generating a warning signal according to the motion trajectory of the object and position information of the predetermined region.

10. A system for detecting an object within a predetermined region around a magnetic resonance imaging device, comprising a memory and a processor, wherein the memory stores a computer program, and the processor is configured to execute the computer program to implement the method for detecting an object within a predetermined region around a magnetic resonance imaging device according to claim 1.
